(19) United States
(12) Patent Application Publication
(10) Pub. No.: US 2025/0180650 A1
(43) Pub. Date: Jun. 5, 2025

(54) BATTERY PROGNOSIS METHOD AND SYSTEM

(71) Applicant: GM GLOBAL TECHNOLOGY OPERATIONS LLC, Detroit, MI (US)

(72) Inventors: Chaitanya Sankavaram, Rochester Hills, MI (US); Ammar Diallo, Troy, MI (US); Ryan B. Moulliet, Farmington Hills, MI (US)

(73) Assignee: GM GLOBAL TECHNOLOGY OPERATIONS LLC, Detroit, MI (US)

(21) Appl. No.: 18/525,954

(22) Filed: Dec. 1, 2023

(51) Int. Cl. G01R 31/367; B60L 58/16; B60L 58/21; G01R 31/389; G01R 31/392

(52) U.S. Cl. CPC G01R 31/367; B60L 58/16; B60L 58/21; G01R 31/389; G01R 31/392; B60L 2240/662

(57) ABSTRACT

An electric vehicle includes an electric motor to propel the electric vehicle and a battery adapted to provide electrical energy to the electric motor for propelling the electric vehicle. The electric vehicle also includes one or more controllers collectively programmed with the following instructions: measure battery data of the battery; use the battery data to create a model of storage capacity of the battery versus distance driven by the electric vehicle; assess a reliability of the model; if the model is assessed as sufficiently reliable, then perform prognosis on the battery using the model; and if the model is assessed as not sufficiently reliable, then adopt a substitute model of storage capacity of the battery versus distance driven by the electric vehicle, the substitute model based on battery data of one or more other vehicles, and perform prognosis on the battery using the substitute model.

This disclosure is in the field of battery prognostics.

Batteries are a source of electrical energy for propulsion of electric vehicles. Predicting premature or excessive degradation of the batteries is useful, including for the purposes of informing a vehicle owner in advance about premature or excessive degradation of the batteries of the vehicle and for providing feedback to Engineering and Manufacturing functions to make going-forward improvements to the batteries.

### SUMMARY

An electric vehicle includes an electric motor to propel the electric vehicle and a battery adapted to provide electrical energy to the electric motor for propelling the electric vehicle. The electric vehicle also includes one or more controllers collectively programmed with the following instructions: measure battery data of the battery; use the battery data to create a model of storage capacity of the battery versus distance driven by the electric vehicle; assess a reliability of the model; if the model is assessed as sufficiently reliable, then perform prognosis on the battery using the model; and if the model is assessed as not sufficiently reliable, then adopt a substitute model of storage capacity of the battery versus distance driven by the electric vehicle, the substitute model based on battery data of one or more other vehicles, and perform prognosis on the battery using the substitute model.

The model may be assessed as not sufficiently reliable if the battery data has an insufficient number of data measurements. Further, the model may be assessed as not sufficiently reliable if the model demonstrates increasing storage capacity versus distance driven. Yet further, the model may be assessed as not sufficiently reliable if the model demonstrates noise.

The one or more other vehicles may be selected based on the one or more other vehicles having operating characteristics similar to operating characteristics of the electric vehicle. Those operating characteristics may include average distance driven per day. Those operating characteristics may, alternatively or additionally, include average ambient temperature.

The prognosis may include comparing projected storage capacities among constituent portions of the battery. The prognosis may alternatively or additionally include comparing projected storage capacity loss among constituent portions of the battery versus a threshold. The prognosis may alternatively or additionally include using the model or the substitute model in combination with internal resistance measurements of the battery.

A second electric vehicle includes an electric motor to propel the electric vehicle and a battery adapted to provide electrical energy to the electric motor for propelling the electric vehicle. The electric vehicle additionally includes one or more controllers collectively programmed with the following instructions: measure battery data of the battery; use the battery data to create a model of storage capacity of the battery versus time in service of the battery in the electric vehicle; assess a reliability of the model; if the model is assessed as sufficiently reliable, then perform prognosis on the battery using the model; and if the model is assessed as not sufficiently reliable, then adopt a substitute model of storage capacity of the battery versus time operated by the electric vehicle, the substitute model based on battery data of one or more other vehicles, and perform the prognosis on the battery using the substitute model.

In the second electric vehicle, the model may be assessed as not sufficiently reliable if the battery data has an insufficient number of data measurements. Further, the model may be assessed as not sufficiently reliable if the model demonstrates increasing storage capacity versus time in service of the battery in the electric vehicle. Yet further, the model may be assessed as not sufficiently reliable if the model demonstrates noise.

In the second electric vehicle, the one or more other vehicles may be selected based on the one or more other vehicles having operating characteristics similar to operating characteristics of the electric vehicle. Those operating characteristics may include average distance driven per day. Those operating characteristics may, alternatively or additionally, include average ambient temperature.

In the second electric vehicle, the prognosis may include comparing projected storage capacities among constituent portions of the battery. The prognosis may alternatively or additionally include comparing projected storage capacity loss among constituent portions of the battery versus a threshold. The prognosis may alternatively or additionally include using the model or the substitute model in combination with internal resistance measurements of the battery.

A method for prognosis of a battery of an electric vehicle includes through one or more controllers, measuring battery data for the battery. The method additionally includes through one or more controllers, using the battery data to create a model of storage capacity of the battery versus distance driven by the electric vehicle or versus time in service of the battery in the electric vehicle. Further, the method includes selecting one or more other vehicles based on the one or more other vehicles having operating characteristics similar to operating characteristics of the electric vehicle. Additionally yet, the method includes creating a substitute model of storage capacity of the battery versus distance driven by the electric vehicle or versus time in service of the battery in the electric vehicle based on battery data of the one or more other vehicles. The method also includes using the model or the substitute model in combination with internal resistance measurements of the battery as a tool for prognosis of the battery and identifying one or more failure root causes of predicted degradation of the battery.

The above summary does not represent every embodiment or every aspect of this disclosure. The above-noted features and advantages of the present disclosure, as well as other possible features and advantages, will be readily apparent from the following detailed description of the embodiments and best modes for carrying out the disclosure when taken in connection with the accompanying drawings and appended claims. Moreover, this disclosure expressly includes combinations and sub-combinations of the elements and features presented above and below.

### BRIEF DESCRIPTION OF THE DRAWINGS

FIG. 1 illustrates an electric vehicle and a back office associated with that electric vehicle.

FIG. 2 illustrates an electrical system of the motor vehicle of FIG. 1.

FIG. 3 illustrates models for capacity versus vehicle mileage for the battery pack of the electric vehicle and for the battery packs of a representative fleet of electric vehicles.

FIG. 4 illustrates a method for modelling battery capacity.

FIG. 5 illustrates clusters into which a fleet of electric vehicles may be grouped based on operating characteristics of the electric vehicles.

FIG. 6 illustrates a method for monitoring battery internal resistance and capacity over time for a plurality of electric vehicles.

FIG. 7 illustrates various root causes for battery failures.

### DETAILED DESCRIPTION

The present disclosure is susceptible of embodiment in many different forms. Representative examples of the disclosure are shown in the drawings and described herein in detail as non-limiting examples of the disclosed principles. To that end, elements and limitations described in the Abstract, Introduction, Summary, and Detailed Description sections, but not explicitly set forth in the claims, should not be incorporated into the claims, singly or collectively, by implication, inference, or otherwise.

For purposes of the present description, unless specifically disclaimed, use of the singular includes the plural and vice versa, the terms “and” and “or” shall be both conjunctive and disjunctive, “any” and “all” shall both mean “any and all”, and the words “including”, “containing”, “comprising”, “having”, and the like shall mean “including without limitation”. Moreover, words of approximation such as “about”, “almost”, “substantially”, “generally”, “approximately”, etc., may be used herein in the sense of “at, near, or nearly at”, or “within 0-5% of”, or “within acceptable manufacturing tolerances”, or logical combinations thereof.

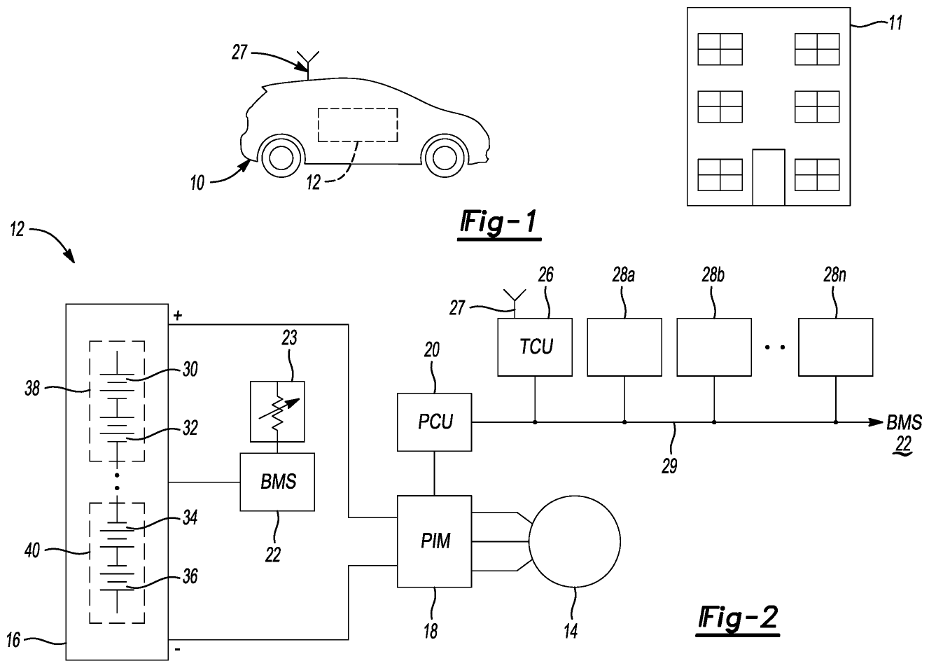

Refer first to FIG. 1, where an electric vehicle 10 is illustrated. Referring additionally to FIG. 2, electric vehicle 10 has an electrical system 12. Electrical system 12 includes an electric powertrain for electric vehicle 10. The electric powertrain for electric vehicle 10 includes an electric motor 14 for propelling electric vehicle 10. Electric motor 14 may be an alternating current (AC) motor. Electrical system 12 also includes a battery pack 16. Battery pack 16 is coupled to a power inverter module (PIM) 18. Battery pack 16 provides propulsive energy to electric motor 14, via switching performed within PIM 18 controlled by a powertrain control unit (PCU) 20. PCU 20 may be a standalone controller, may be integrated with PIM 18, or may be integrated with other controllers in electrical system 12 of electric vehicle 10.

Electric vehicle 10 may be any vehicle that is propelled in whole in part using electrical energy and may include full-electric and hybrid-electric vehicles. Further, electric vehicle 10 may be any style of vehicle, such as a car, truck, van, sport-utility vehicle, motorcycle, bicycle, scooter, boat, aircraft or the like.

Battery pack 16 may include multiple battery cells that are arranged in battery cell groups. Four of such cell groups, cell group 30, cell group 32, cell group 34, and cell group 36, are illustrated. Battery pack 16 may have any number of battery cells and cell groups. The cell groups may be grouped in battery modules, such as battery module 38, which contains cell group 30 and cell group 32, and battery module 40, which contains cell group 34 and cell group 36. Though two cell groups are illustrated in each of battery module 38 and battery module 40, that is simply for convenience. The battery modules may contain any number of cell groups, and battery pack 16 may have any number of battery modules. The battery cells, cell groups, and battery modules referred to herein may be referred to as constituent portions of battery pack 16.

Electrical system 12 may also include a battery monitoring system (BMS) controller 22 that monitors battery pack 16. Specifically, BMS controller 22 may monitor the state of charge of battery pack 16 as well as the charging and discharging of battery pack 16. Additionally, BMS controller 22 may monitor the state of charge of each battery module, such as battery module 38, as well as the charging and discharging thereof. Additionally yet, BMS controller 22 may monitor the state of charge of each cell group, such as cell group 30, as well as the charging and discharging thereof. BMS controller 22 may also monitor the internal resistances of battery pack 16 and/or cell groups and/or battery modules thereof, such as by monitoring charge and discharge currents and voltages of battery pack 16 and the cell groups and battery modules thereof, with internal resistance being the quotient of voltage over current.

BMS controller 22 may be integrated within battery pack 16 or may be separate from battery pack 16. BMS controller 22 is to be understood to have connections as needed for monitoring battery pack 16 as a whole, as well as monitoring each cell group and each battery module that BMS controller 22 monitors. BMS controller 22 is understood to have sufficient resources (e.g., microcontroller, software, inputs, outputs, memory, and the like) to perform the tasks ascribed to it herein.

Electrical system 12 may have a temperature sensor 23 that measures the ambient temperature in the vicinity of electric vehicle 10. Temperature sensor 23 may be connected to BMS controller 22 or to another controller in electrical system 12.

In addition to powertrain control unit 20 and BMS controller 22, electric vehicle 10 may contain several other controllers in electrical system 12. For instance, electric vehicle 10 may contain a telematics control unit (TCU) 26 that allows electric vehicle 10 to engage in cellular telecommunications, including cellular data communications. Such telecommunications may include telecommunications with a “back office” 11 operated by the manufacturer of electric vehicle 10. (OnStar®, operated by General Motors, is an example of one such back office.) TCU 26 may have, or may be connected to, a suitable antenna 27 that facilitates such communication. Electric vehicle 10 may also have any number of other controllers (illustrated generically in FIG. 2 as controller 28a, controller 28b, and controller 28n) to control other functions of electric vehicle 10, such as braking, infotainment, steering, lighting, and the like. The various controllers on electric vehicle 10 may be networked together by one or more data buses 29 or by individual electrical circuits, and the controllers may therefore share data in performing their various tasks. Further, electrical system 12 of electric vehicle 10 may be partitioned differently than as shown in FIG. 2, with the tasks performed by or shared with different or other controllers.

The various calculations, comparisons, and other tasks to be hereinafter described in this disclosure may be performed by one controller or collectively by the several controllers that may be networked together in electrical system 12 of electric vehicle 10. Each of those controllers, individually and/or collectively, are understood to have sufficient electronic resources (microprocessor, memory, inputs, outputs, software, cellular network access device (NAD)) to perform the functions described in this disclosure. Some of the functions described herein may be performed by computers offboard electric vehicle 10, such as computers in back office 11 or in the cloud.

The one or several controllers may be responsive to “instructions”, which may comprise one or more software commands. Further, one instruction may comprise one or more additional instructions.

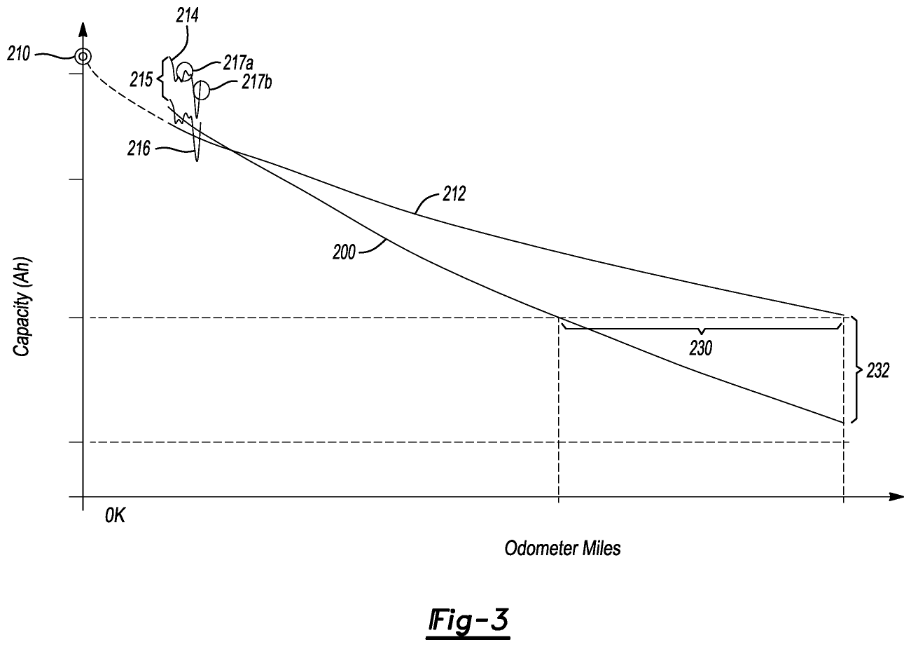

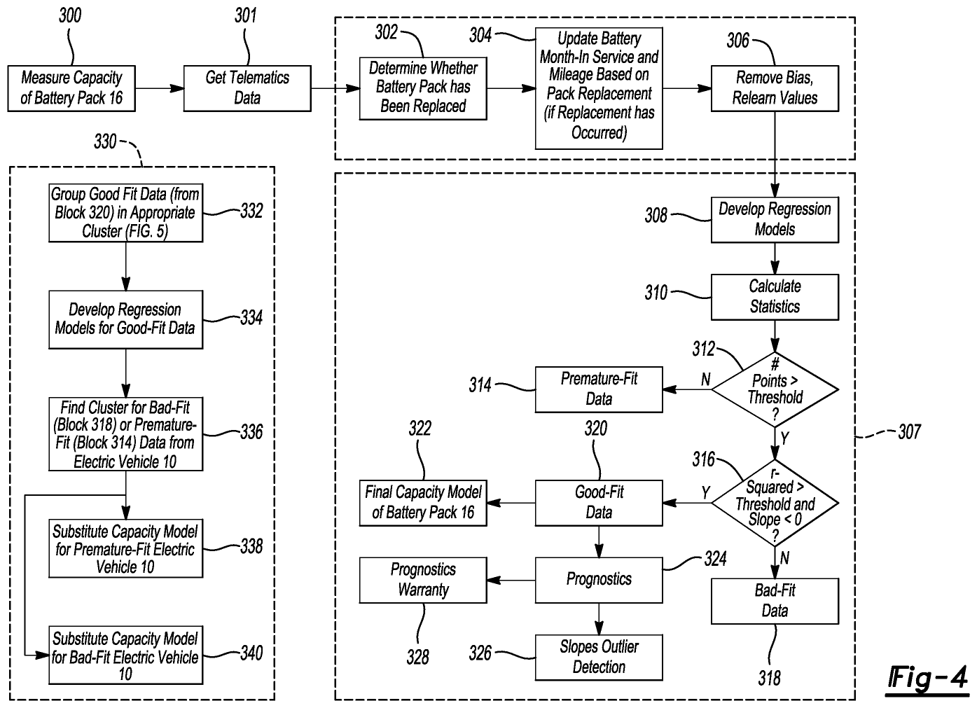

Refer now to FIG. 3 and FIG. 4, which illustrate a battery capacity modelling algorithm. A function of that algorithm may be to generate a model, represented by curve 200, of battery storage capacity versus distance driven (that is, odometer reading in, say, miles or kilometers) for battery pack 16.

At block 300, battery data, namely, the storage capacity of battery pack 16 is measured or calculated. BMS controller 22, which monitors the charging and discharging of battery pack 16, may understand the present storage capacity of battery pack 16, in ampere-hours, kilowatt-hours, or another suitable unit of storage capacity. This capacity may be calculated regularly on an ongoing basis. Storage capacities of the cell groups and battery modules within battery pack 16 may also be measured or calculated on an ongoing basis.

At block 301, telematics data may be gathered via TCU 26. The telematics data may be provided to back office 11. The telematics data may include the measured capacity of battery pack 16 or constituent portions (cell groups, battery modules) thereof. The telematics data may also include “good-fit” data (from block 320). At block 302, it is determined whether battery pack 16 was replaced. At block 304, the months-in-service and distance driven by electric vehicle 10 for battery pack 16 is then updated if battery pack 16 has been replaced with a new battery pack. At block 306, any bias generated by having replaced battery pack 16 with a new battery pack (the new battery pack having a beginning-of-life (BOL) capacity that is well-known in a tight tolerance range) is eliminated and the algorithms described herein are reset/relearned to reflect the battery pack replacement.

The measured or calculated storage capacity is then used at the beginning of a data classification portion 307 of the algorithm, where the data for the capacity of battery pack 16 may be processed, filtered, and classified. The calculated or measured capacity data for battery pack 16 is fit at block 308 into a regression model of storage capacity versus distance driven for electric vehicle 10. Statistics of the regression model are calculated at block 310. Those statistics may include slope, root-mean-square error, and r-squared statistics. It is then determined at block 312 whether the number of data points in the regression model is sufficient (that is, above a predetermined threshold) to conclude that the model of capacity versus odometer reading for battery pack 16 may be expected to be reliable for characterizing battery pack 16. As one nonlimiting example, the number of data points judged as “sufficient” may be two to three data points per month over a period of five or six months. If the conclusion at block 312 is NO (that is, the number of data points is not sufficient), then the model of capacity versus odometer reading for battery pack 16 is determined at block 314 to be based on insufficient data and flagged as being a “premature-fit data” model. If the conclusion at block 312 is that there are enough data points in the regression model, then the method proceeds to block 316. At block 316, the statistics from the model are tested to determine the reliability of the model, such as by comparison with thresholds suitable for the specific statistics being tested. For instance, the r-squared for the model may be compared with a threshold, which may be 95%. Also, at block 316, it may be determined whether the slope of the modelled curve is negative or whether the slope of the modelled curve or portions thereof is positive; batteries have decreasing capacity with increasing mileage, so if the data are “good”, the curve would be expected to have a negative slope. If the statistics being tested for reliability do not pass their respective tests (e.g., the r-squared value for the data that generated the model is not above the threshold or the slope of the model's curve is not negative or the slope of the modelled curve or portions thereof is positive), then it may be concluded that the data generating the model is a bad fit (e.g., the data may be considered “noisy”). The data may accordingly be flagged as “bad-fit data” at block 318. It is apparent that tests at blocks 312 and 316 may determine whether a sufficiently reliable model may be generated using the battery data.

However, at block 316, if it is determined that the statistics being tested pass their respective tests (e.g., the r-squared for the data is above the threshold and the slope of the curve representing the model is reliably negative), then it may be concluded that the data that generated the model is “good-fit data” (that is, the data is of quantity and quality to generate a reliable model of battery pack 16), and the data may be flagged as such at block 320. Thus, the final prediction of the storage capacity over distance driven of battery pack 16 during the life of battery pack 16 may be identified at block 322. That final prediction may be used for prognostics of battery pack 16 (block 324). This may include prognostics about whether battery pack 16 is likely to have a capacity that is less than expected over its lifetime (block 326) and to predict the likelihood of whether battery pack 16 may be expected to be the subject of a warranty claim (block 328). This information may be sent to back office 11 and may be used to communicate to the owner of electric vehicle 10 that battery pack 16 may have a less than expected lifetime.

If the answer at block 316 is NO, the data may be characterized as “bad-fit” data at block 318.

Once data from electric vehicle 10 has been characterized as “good-fit data,” that data from block 320 may be passed to block 332.

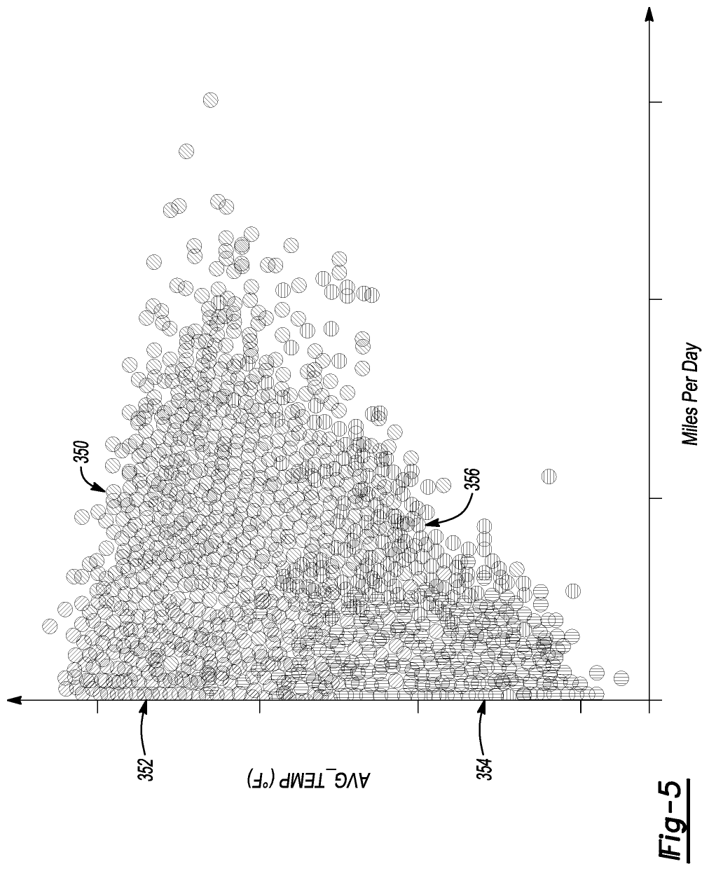

With further reference to FIG. 4, a Clustering and Regression Prediction section 330 portion of the algorithm disclosed herein may then be entered. There, beginning at block 332, “good-fit data” from a fleet of vehicles may be clustered. (An automaker that has access to data from a fleet of vehicles via back office 11 may be able to use that data to significant advantage here.) That “good-fit data” may then be clustered based on the average distance driven per day (e.g., miles or kilometers), on the x-axis, for the vehicles in that fleet and the average ambient temperatures, on the y-axis, at which the vehicles in that fleet are operated. Clustering from a population of vehicles is illustrated at FIG. 5, where cluster 350, cluster 352, cluster 354, and cluster 356 are illustrated. “Regression” as used herein may be linear regression or other regression analysis.

At block 334, regression models are generated for the “good-fit data” of each cluster. At block 336, the model from the appropriate cluster may be selected as a “placeholder” or “substitute” for the actual model of battery pack 16 if battery pack 16 has a “premature-fit data” or “bad-fit data” model. The method proceeds to block 338 if battery pack 16 has a “premature-fit data” model and the regression model for the appropriate cluster is used provisionally as the capacity versus mileage model for battery pack 16. However, from block 336 the method proceeds to block 340 if battery pack 16 has a “bad-fit data” model and the regression model for the appropriate cluster is used provisionally as the predicted capacity versus distance model for battery pack 16. As such, it may be assumed, possibly provisionally since battery pack 16 doesn't yet have its own “good-fit data” model, that the model of battery pack 16 may be comparable to the models of the other vehicles in the same cluster. That is, it may be provisionally assumed that the model of capacity versus miles driven for battery pack 16 of electric vehicle 10 will be generally consistent with the “good-fit data” models of other vehicles operated in similar conditions.

With reference to FIG. 3, an example of a “bad-fit data” or “premature-fit data” model, and correction therefor, is illustrated. (The x-axis if the graph of FIG. 3 may be distance travelled by electric vehicle 10, as may be represented by miles or kilometers registered on the odometer of electric vehicle 10. The y-axis of the graph of FIG. 3 may be the electrical storage capacity of battery pack 16 in suitable units, such as amp-hours, kilowatt-hours, or other suitable units.) It may first be assumed that at the beginning of life (“BOL”), labelled as “OK” (or zero thousand) miles or kilometers on the x-axis of FIG. 3, a new battery pack has a capacity that is known within a tight tolerance, as that battery has just been manufactured and has not experienced any use or aging. As one example, the BOL capacity 210 of battery pack 16 may be about 181 ampere-hours, as illustrated in the exemplary example of FIG. 3. A regression model using “good-fit data” from vehicles in the same cluster as electric vehicle 10 may be depicted as curve 212 in FIG. 3. When a model for battery pack 16 is calculated, and if the model is based on “bad-fit data” or “premature-fit data”, the model may reflect a bias. A “raw” capacity curve segment with bias is shown as curve segment 214. That bias 215 may be corrected by knowing that curve 212 would be expected to have exhibited a decrease in capacity from BOL 210 that would generally result in the curve for battery pack 16 being at curve segment 216. The calculated model for battery pack 16 is adjusted accordingly.

Further, curve segment 214 (a segment of the “raw” capacity model for battery pack 16 before bias correction) and curve segment 216 (a segment of the “raw” capacity model for battery pack 16 after bias correction) may exhibit noise. Battery storage capacity is naturally expected to decrease over time. However, portions of curve 200, illustrated by portions 217a and 217b that show upward (or positive) slope, evidence noise in capacity data for battery pack 16. Such noise may be grounds for concluding that the model for battery pack 16 is based on “bad-fit data” (see also block 316 of FIG. 4).

Calculating a capacity versus mileage model based on “bad-fit data” or “premature-fit data” for battery pack 16 of electric vehicle 10 may result in curve 200. However, substituting an alternative “good-fit” data model based on a similarly-situated cluster of vehicles may result in curve 212. Using curve 200 may result in a premature prognosis that battery pack 16 will have a shortened lifetime (that is, erring on lifetime of battery pack 16 by an amount 230, say, because the long-term capacity degradation predicted by curve 200 is greater than that for curve 212). Or, using curve 200 may result in a premature prognosis that battery pack 16 will have more degradation in capacity (that is, erring on the amount of degradation by an amount 232, say, because the long-term capacity degradation predicted by curve 200 is greater than that for curve 212). Thus, for battery prognosis purposes, the model resulting in curve 212 may be adopted as a substitute model for the actual model for battery pack 16 until battery pack 16 has a model that has been generated using “good-fit data”.

While the graph of FIG. 3 is illustrated as being storage capacity (y-axis) versus distance driven (x-axis), the models may alternatively or additionally be generated based on storage capacity versus time in service of battery pack 16 in electric vehicle 10 (such as the number of months that battery pack 16 has been installed in electric vehicle 10). The models may alternatively or additionally be generated based on storage capacity versus time of operation of electric vehicle 10 with battery pack 16 installed (that is, the cumulative elapsed time that electric vehicle 10 has actually been propelled using battery pack 16). The discussion in this disclosure should be understood accordingly. Further, prognosis as described herein based on a model of storage capacity versus distance driven and prognosis based on a model of storage capacity versus one or both of the time measures discussed in this paragraph may be used in combination; they are not mutually exclusive.

Once a model for battery pack 16 has been developed using either “good-fit data” or a provisional or substitute model (in the case of “premature-fit data” or “bad-fit data”), it may be used for prognosis of battery pack 16 and/or cell groups and/or battery modules thereof. Here, “prognosis” is used to refer to a prediction of a future performance or future condition of battery pack 16 and/or cell groups and/or battery modules thereof. Certainly, a first prognosis is provided by the capacity versus odometer reading model itself (whether a model such as represented by curve 200 if it resulted from “good-fit data” or a substitute model such as a model represented by curve 212). The model predicts the storage capacity of battery pack 16 over distance driven by electric vehicle 10.

“Prognosis” may also refer in this disclosure to predicting the difference in capacity among cell groups of battery pack 16 and/or among battery modules of battery pack 16; this may be used, for instance, to isolate one or more battery cells or battery modules that would be predicted to act differently than the others, possibly due to one or more expected failure modes or failure mechanisms. “Prognosis” may also refer in this disclosure to predicting which failure modes or failure mechanisms may be developing or may develop in battery pack 16 and/or cell groups and/or battery modules thereof.

Prognosis may be done via one or more capacity monitoring algorithms. One such algorithm may compare capacity models of various cell groups within battery pack 16 at any particular odometer reading. Various comparisons may be performed, such as the following:

TABLE 1

| | |
|---|---|
| (a) | max[C_{CGi}, i ϵ [0, n]] − min[C_{CGi}, i ϵ [0, n]] |
| (b) | max[C_{CGi}, i ϵ [0, n]] − avg[C_{CGi}, i ϵ [0, n]] or |
| | max[C_{CGi}, i ϵ [0, n]] − median[C_{CGi}, i ϵ [0, n]] |
| (c) | avg[C_{CGi}, i ϵ [0, n]] − min[C_{CGi}, i ϵ [0, n]] or |
| | median[C_{CGi}, i ϵ [0, n]] − min[C_{CGi}, i ϵ [0, n]] |

where CGᵢ is a cell group (“CG”) number of battery pack 16, n is the total number of cell groups in battery pack 16, “max” is the maximum capacity among the “n” cell groups, “min” is the minimum capacity among the “n” cell groups, “avg” is the average capacity of all “n” cell groups, and “median” is the median capacity of all “n” cell groups. If one or more of the values in the above table are above a threshold, a flag for predicted loss of storage capacity of battery pack 16 may be set, and the suspect cell group(s) may be predicted to become faulty (e.g., to have a shorter than design-specified life or a greater than design-specified loss of storage capacity over time). Further, the suspect cell group(s) may be identified for the purpose of prognostics directed to the root cause(s) for the predicted loss of storage capacity. This algorithm may be employed with reference to any specific future odometer reading. By way of illustration, row (a) in Table 1 illustrates calculation of the difference between the maximum estimated capacity of a cell group and the minimum estimated capacity of a cell group and compares this difference to a threshold. Row (b) in Table 1 illustrates calculation of the difference between the maximum estimated capacity of a cell group and the average or median of the estimated capacities of all “n” cell groups and compares this difference to a threshold. Row (c) in Table 1 illustrates calculation of the difference between average or median of the estimated capacities of all “n” cell groups and the minimum estimated capacity of a cell group and compares this difference to a threshold.

Instead of doing the foregoing prognosis at a cell group level, it may be done at a battery module level (e.g., among battery module 38 and battery module 40 and any other battery modules within battery pack 16). For the purpose of prognosis at the cell group level, BMS controller 22 should be understood to have electrical connections within battery pack 16 at the cell group level. For the purpose of prognosis at the module level, BMS controller 22 should be understood to have electrical connections within battery pack 16 at the module level.

Another algorithm that may be employed may use predicted estimated capacity loss (which may also be referred to as estimated capacity fade) for individual cell groups. In this case a percentage capacity fade calculation over time may be calculated as follows:

$$Capacity {Fade}_{i} ( \% ) = ( 1 - \frac{CGi\_Capacity ( t )}{CGi\_Capacity ( 0 )} ) * 100 , i ϵ [ 0 , n ] ,$$

where CGᵢ_Capacity(t) is the capacity of cell group CGᵢ at any selected time t and CGᵢ_Capacity(0) is the capacity of cell group CGᵢ at time 0. If any of the capacity fade calculations are above a threshold, flag(s) for the suspect cell group(s) may be set and the suspect cell group(s) identified. Such cell group(s) may be expected to become faulty (e.g., to have a shorter than design-specified life or a greater than design-specified loss of storage capacity over time).

Instead of doing the above prognosis at a cell group level, it may be done at a module level (e.g., among battery module 38 and battery module 40 and any other battery modules within battery pack 16). BMS controller 22 should be understood to have connections within battery pack 16 to have electrical connections at the within battery pack 16 at the module level.

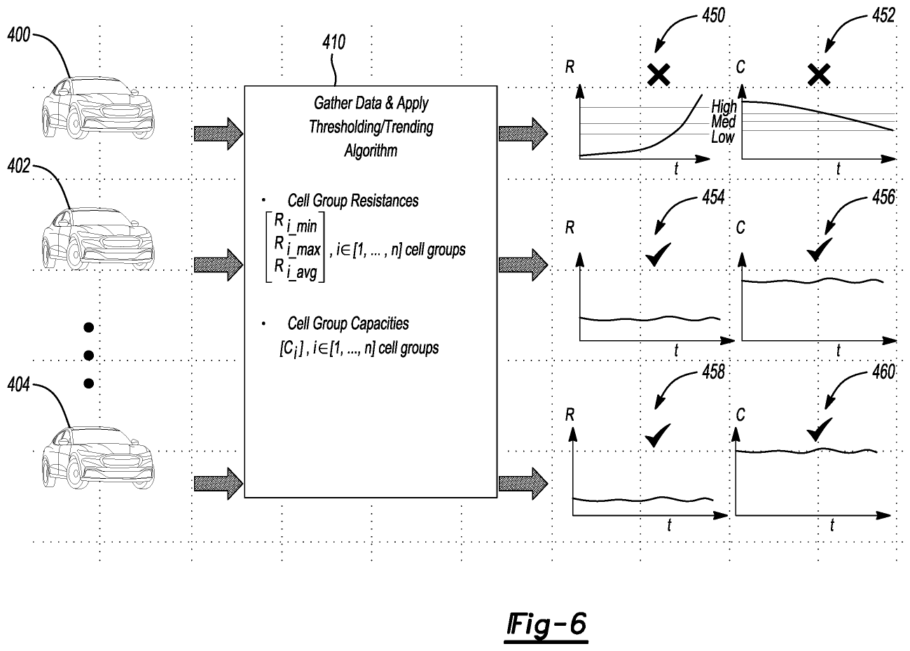

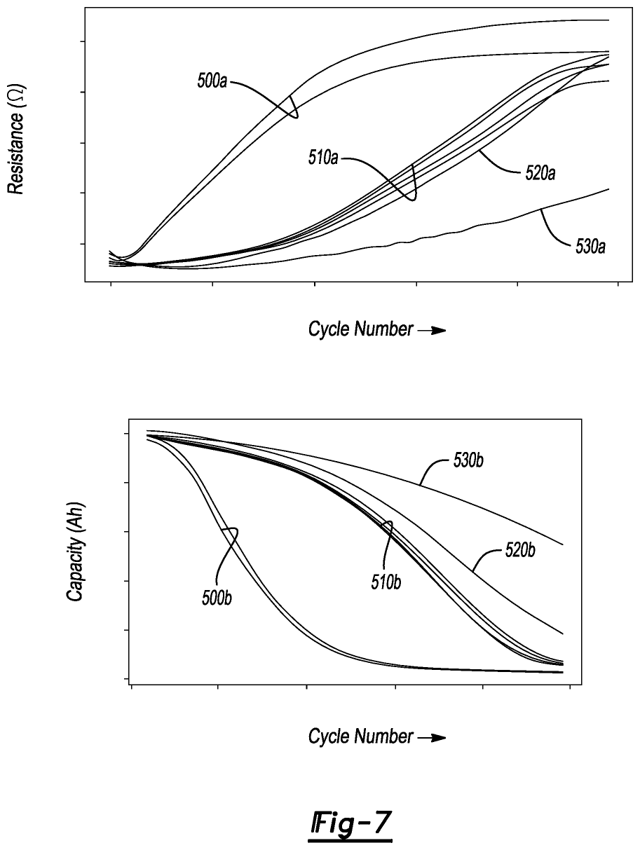

Monitoring capacity of battery pack 16 as hereinabove described may also be coupled with monitoring the resistance of battery pack 16 over time, which is an additional prognosis tool. (Such resistance monitoring can be at the cell group, module, or battery pack level, can be done periodically, and the data extrapolated into the future to create a resistance versus odometer reading model or a resistance versus time model.) For instance, take the illustration of three vehicles, vehicle 400, vehicle 402, and vehicle 404 in FIG. 6. Prognostics via a combined algorithm 410 that examines projected cell group resistances over time and projected cell group capacities over time may illustrate that over comparable timeframes, one or more cell groups of the battery pack of electric vehicle 400 may illustrate a more pronounced increase in resistance over time and/or a more pronounced decrease in capacity over time (see graphs 450 and 452 of resistance (R) versus time and storage capacity (C) versus time, relative to the battery packs of vehicle 402 (graph 454 and graph 456) and vehicle 404 (graph 458 and graph 460). This may be used as a prognostic tool, with the curves illustrated in FIG. 6 used through physics-based analysis or machine learning to isolate root causes of predicted battery degradation. The curves illustrated in FIG. 6 may be compared to the curves of FIG. 7, which may have been generated based on actual laboratory diagnosis of failure root causes in batteries from a fleet of vehicles. Such root causes may be, say, high moisture content in the battery electrolyte (curves 500a and 500b in FIG. 7), metal contamination of the battery (curves 510a and 510b in FIG. 7), loss of battery electrolyte (curves 520a and 520b in FIG. 7) compared with a baseline (curves 530a and 530b in FIG. 7) demonstrated over a vehicle and battery population. Lithium plating of a battery electrode may also be a root cause of battery degradation. Recall that a vehicle manufacturer with a large fleet of its customers' vehicles on the road and access to data about the vehicles via telecommunications network that includes back office 11 may have access to a large amount of data. These analyses of battery degradation root causes may be fed back to the Engineering and Manufacturing functions responsible for battery pack 16 in order to make going-forward design and manufacturing improvements as appropriate.

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the present disclosure.

Furthermore, the embodiments shown in the drawings or the characteristics of various embodiments mentioned in the present description are not necessarily to be understood as embodiments independent of each other. Rather, it is possible that each of the characteristics described in one of the examples of an embodiment can be combined with one or a plurality of other desired characteristics from other embodiments, resulting in other embodiments not described in words or by reference to the drawings. Accordingly, such other embodiments fall within the framework of the scope of the appended claims. Moreover, this disclosure expressly includes combinations and sub-combinations of the elements and features presented above and below.

What is claimed is:

1. An electric vehicle comprising:
an electric motor to propel the electric vehicle;
a battery adapted to provide electrical energy to the electric motor for propelling the electric vehicle; and
one or more controllers collectively programmed with the following instructions:
measure battery data of the battery;
use the battery data to create a model of storage capacity of the battery versus distance driven by the electric vehicle;
assess a reliability of the model;
if the model is assessed as sufficiently reliable, then perform prognosis on the battery using the model; and
if the model is assessed as not sufficiently reliable, then adopt a substitute model of storage capacity of the battery versus distance driven by the electric vehicle, the substitute model based on battery data of one or more other vehicles, and perform prognosis on the battery using the substitute model.

2. The electric vehicle of claim 1, further comprising selecting the one or more other vehicles based on the one or more other vehicles having operating characteristics similar to those of the electric vehicle.

3. The electric vehicle of claim 2, wherein the operating characteristics include average distance driven per day.

4. The electric vehicle of claim 2, wherein the operating characteristics include average ambient temperature.

5. The electric vehicle of claim 1, wherein the model is assessed as not sufficiently reliable if the battery data has an insufficient number of data measurements.

6. The electric vehicle of claim 1, wherein the model is assessed as not sufficiently reliable if the model demonstrates increasing storage capacity versus distance driven or if the model demonstrates noise.

7. The electric vehicle of claim 1, wherein the prognosis includes comparing projected storage capacities among constituent portions of the battery.

8. The electric vehicle of claim 1, wherein the prognosis includes comparing projected storage capacity loss among constituent portions of the battery against a threshold.

9. The electric vehicle of claim 1, wherein the prognosis includes using the model or the substitute model in combination with internal resistance measurements of the battery.

10. An electric vehicle comprising:
an electric motor to propel the electric vehicle;
a battery adapted to provide electrical energy to the electric motor for propelling the electric vehicle; and
one or more controllers collectively programmed with the following instructions:
measure battery data of the battery;
use the battery data to create a model of storage capacity of the battery versus time in service of the battery in the electric vehicle;
assess a reliability of the model;
if the model is assessed as sufficiently reliable, then perform prognosis on the battery using the model; and
if the model is assessed as not sufficiently reliable, then adopt a substitute model of storage capacity of the battery versus time in service of the battery in the electric vehicle, the substitute model based on battery data of one or more other vehicles, and perform the prognosis on the battery using the substitute model.

11. The electric vehicle of claim 10, further comprising selecting the one or more other vehicles based on the one or more other vehicles having operating characteristics similar to those of the electric vehicle.

12. The electric vehicle of claim 11, wherein the operating characteristics include average distance driven per day.

13. The electric vehicle of claim 11, wherein the operating characteristics include average ambient temperature.

14. The electric vehicle of claim 10, wherein the model is assessed as not sufficiently reliable if the battery data has an insufficient number of data measurements.

15. The electric vehicle of claim 10, wherein the model is assessed as not sufficiently reliable if the model demonstrates increasing storage capacity versus time in service of the battery in the electric vehicle or if the model demonstrates noise.

16. The electric vehicle of claim 10, wherein the prognosis includes:
comparing storage capacities among constituent portions of the battery; and
identifying the battery as faulty based on the comparing.

17. The electric vehicle of claim 10, wherein the prognosis includes:
comparing storage capacity loss among constituent portions of the battery; and
identifying the battery or constituent portions thereof as faulty based on the comparing.

18. The electric vehicle of claim 10, wherein the prognosis includes using the model or the substitute model in combination with internal resistance measurements of the battery.

19. A method for prognosis of a battery of an electric vehicle, the method comprising:
through one or more controllers, measuring battery data for the battery;
through one or more controllers, using the battery data to create a model of storage capacity of the battery versus distance driven by the electric vehicle or versus time in service of the battery in the electric vehicle;
selecting one or more other vehicles based on the one or more other vehicles having operating characteristics similar to operating characteristics of the electric vehicle;
creating a substitute model of storage capacity of the battery versus distance driven by the electric vehicle or versus time in service of the battery in the electric vehicle based on battery data of the one or more other vehicles;
using the model or the substitute model in combination with internal resistance measurements of the battery for prognosis of the battery; and
identifying one or more failure root causes of degradation of the battery predicted by the prognosis.

20. The method of claim 19, wherein the prognosis includes:
comparing storage capacities or storage capacity loss among constituent portions of the battery; and
identifying the battery as faulty based on the comparing.
